(19) United States
(12) Patent Application Publication
(10) Pub. No.: US 2025/0149293 A1
(43) Pub. Date: May 8, 2025

(54) PLASMA GENERATION CIRCUIT AND SUBSTRATE PROCESSING DEVICE INCLUDING THE SAME

(71) Applicant: Samsung Electronics Co., Ltd., Suwon-si (KR)

(72) Inventors: Jaewon Jeong, Suwon-si (KR); Dongchan Jeon, Suwon-si (KR); Kyungsun Kim, Suwon-si (KR); Sungyeol Kim, Suwon-si (KR); Yongwon Cho, Suwon-si (KR)

(21) Appl. No.: 18/747,933

(22) Filed: Jun. 19, 2024

(30) Foreign Application Priority Data
Nov. 2, 2023 (KR) 10-2023-0150292

(51) Int. Cl. H01J 37/32

(52) U.S. Cl. CPC H01J 37/3211; H01J 37/32449

(57) ABSTRACT

A plasma generation circuit includes a high frequency power source configured to generate a first high frequency current; a current divider comprising a first capacitor and a variable capacitor and configured to divide the first high frequency current into a second high frequency current and a third high frequency current; an antenna assembly comprising a center antenna connected to the current divider and through which the second high frequency current is configured to flow, and an edge antenna connected in to the current divider and through which the third high frequency current is configured to flow, the antenna assembly being configured to induce generation of an inductively coupled plasma; a first coil coupled inductor configured to allow the second high frequency current to flow therethrough; and a second coil coupled inductor configured to allow the third high frequency current to flow therethrough and adjacent to the first coil coupled inductor.

### CROSS-REFERENCE TO RELATED APPLICATION

This application is based on and claims priority under 35 U.S.C. § 119 to Korean Patent Application No. 10-2023-0150292, filed on Nov. 2, 2023, in the Korean Intellectual Property Office, the disclosure of which is incorporated by reference herein in its entirety.

### BACKGROUND

Aspects of the inventive concept relate to a plasma generation circuit and a substrate processing device including the same.

One example of a process for manufacturing a semiconductor device is a plasma process including plasma-induced deposition, plasma etching, and plasma cleaning. Recently, with the miniaturization and high integration of semiconductor devices, the influence of slight errors in a plasma process on the quality of semiconductor products has increased. Accordingly, various technologies for precisely simulating a plasma process have been proposed.

### SUMMARY

Aspects of the inventive concept provide a plasma generation circuit with improved reliability.

Aspects of the inventive concept also provide a substrate processing device including a plasma generation circuit with improved reliability.

According to an aspect of the inventive concept, a plasma generation circuit includes a high frequency power source configured to generate a first high frequency current; a current divider comprising a first capacitor and a variable capacitor and configured to divide the first high frequency current into a second high frequency current and a third high frequency current; an antenna assembly comprising a center antenna connected to the current divider and through which the second high frequency current is configured to flow, and an edge antenna connected in to the current divider and through which the third high frequency current is configured to flow, the antenna assembly being configured to induce generation of an inductively coupled plasma; a first coil coupled inductor configured to allow the second high frequency current to flow therethrough; and a second coil coupled inductor configured to allow the third high frequency current to flow therethrough and adjacent to the first coil coupled inductor . . . .

According to another aspect of the inventive concept, a plasma generation circuit includes a high frequency power source configured to generate a first high frequency current; a current divider comprising a first capacitor and a variable capacitor and configured to divide the first high frequency current into a second high frequency current and a third high frequency current; an antenna assembly comprising a center antenna connected to the current divider and through which the second high frequency current is configured to flow, and an edge antenna connected to the current divider and through which the third high frequency current is configured to flow, the antenna assembly being configured to induce generation of an inductively coupled plasma; a first busbar coupled inductor configured to allow the second high frequency current to flow therethrough; a second busbar coupled inductor configured to allow the third high frequency current to flow therethrough, and disposed to be apart from the first busbar coupled inductor in a horizontal direction; a first busbar connection portion connected in series with the first busbar coupled inductor; and a second busbar connection portion connected in series with the second busbar coupled inductor.

According to another aspect of the inventive concept, a substrate processing device includes a chamber configured to define a space for plasma-processing a substrate, a gas supply portion configured to supply plasma gas to the chamber, and a plasma generation circuit configured to induce a plasma generation reaction of the plasma gas. The chamber includes an upper housing, a lower housing disposed below the upper housing, a window disposed between the upper housing and the lower housing, and a chuck configured to support the substrate. The plasma generation circuit includes a high frequency power source configured to generate a first high frequency current, a current divider including a first capacitor and a variable capacitor and configured to divide the first high frequency current into a second high frequency current and a third high frequency current, an antenna assembly comprising a center antenna connected to the current divider and through which the second high frequency current is configured to flow, and an edge antenna connected to the current divider and through which the third high frequency current is configured to flow, the antenna assembly being configured to induce generation of an inductively coupled plasma, and a coupled inductor disposed between the current divider and the antenna unit. The center antenna and the edge antenna are provided to generate a first electromagnetic inductive coupling by mutual induction, the coupled inductor is provided to generate a second electromagnetic inductive coupling in a direction opposite to a direction of the first electromagnetic inductive coupling, and the first electromagnetic inductive coupling is canceled by the second electromagnetic inductive coupling.

### BRIEF DESCRIPTION OF THE DRAWINGS

Embodiments will be more clearly understood from the following detailed description taken in conjunction with the accompanying drawings in which:

FIG. 1 is a circuit diagram of a plasma generation circuit including a coil inductor, according to an embodiment;

FIG. 2 is a circuit diagram of a plasma generation circuit including a coil inductor, according to another embodiment;

FIG. 3 is a circuit diagram of a plasma generation circuit including a busbar inductor, according to an embodiment;

FIG. 4 is a circuit diagram of a plasma generation circuit including a busbar inductor, according to another embodiment;

FIG. 5 is a graph of a current ratio according to a position of a variable capacitor, according to an embodiment;

FIG. 6 is a diagram for describing a substrate processing device including a coil inductor, according to an embodiment;

FIG. 7A is a diagram for describing a substrate processing device including a busbar inductor, according to an embodiment;

FIG. 7B is a diagram for describing a substrate processing device including a busbar inductor, according to another embodiment;

FIG. 8 is a flowchart of a semiconductor device manufacturing method including plasma process simulation, according to an embodiment; and

FIG. 9 is a block diagram illustrating a computing system according to an embodiment.

### DETAILED DESCRIPTION OF THE EMBODIMENTS

As the present embodiments allow for various changes and numerous forms, certain embodiments will be illustrated in the drawings and described in detail in the written description. However, this is not intended to limit the present embodiments to specific disclosed forms. In addition, embodiments described herein are merely examples, and various modifications may be made thereto from these embodiments.

The use of all illustrations or illustrative terms in the embodiments is simply to describe the technical ideas in detail, and the scope of the inventive concept is not limited by the illustrations or illustrative terms unless they are limited by claims.

Unless otherwise stated below, in the present specification, a vertical direction is referred to as the Z direction and each of a first direction and a second direction may each be referred to as vertical directions perpendicular to the Z direction. The first direction may be referred to as the X direction and the second direction may be referred to as the Y direction. The X direction and the Y direction may be horizontal directions. A vertical level may refer to the height level in the vertical direction (the Z direction) (e.g., a height above a reference plane such as a top or bottom surface of a substrate). The horizontal width may refer to the length in the horizontal direction (the X direction and/or the Y direction) and the vertical length may refer to the length in the vertical direction (the Z direction).

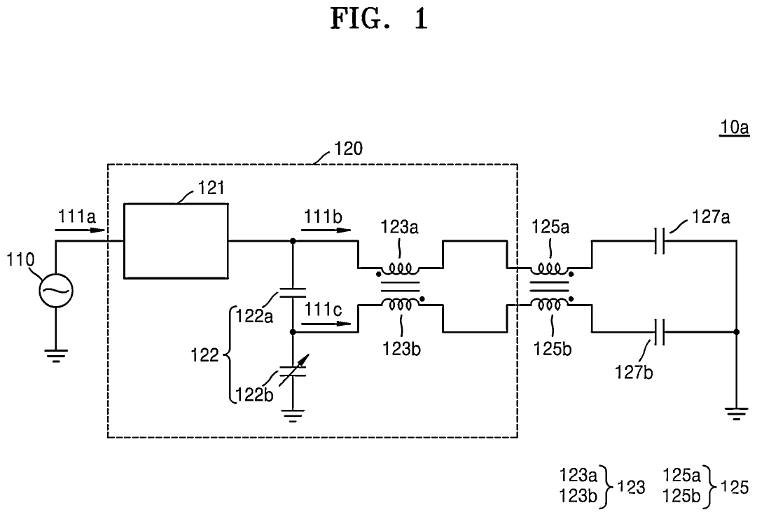

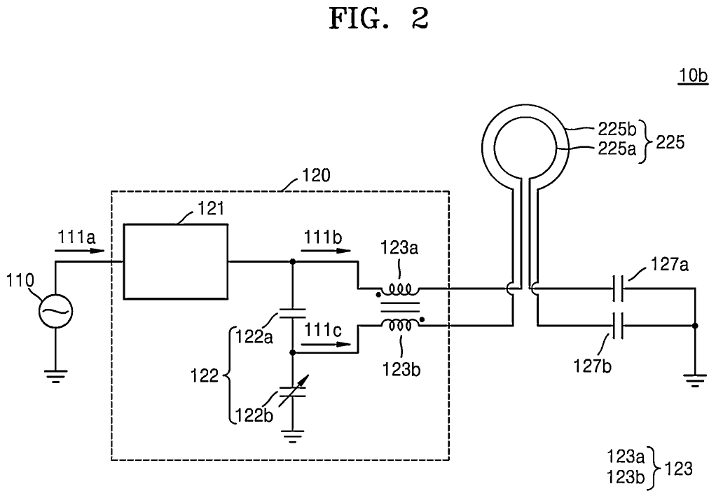

FIG. 1 is a circuit diagram of a plasma generation circuit including a coil inductor, according to an embodiment. FIG. 2 is a circuit diagram of a plasma generation circuit including a coil inductor, according to another embodiment.

Referring to FIGS. 1 and 2, a plasma generation circuit 10a may include a high frequency power source 110 and a match circuit 120.

The high frequency power source 110 may generate a first high frequency current 111a. As an example, the high frequency power source 110 may be a radio frequency (RF) power source. The first high frequency current 111a supplied by the RF power source may be RF power. The first high frequency current 111a may be a sinusoidal wave with a set frequency. However, the inventive concept is not limited thereto, and signals of various waveforms, such as triangular waves, may be generated. The first high frequency current 111a may have a frequency of tens of MHz or more. For example, the first high frequency current 111a applied through the high frequency power source 110 may have a frequency of about 10 MHz to about 60 MHz.

The match circuit 120 may include a matcher 121, a current divider 122, and a coil coupled inductor 123.

The current divider 122 may include a first capacitor 122a and a variable capacitor 122b. In the circuit diagram, the first capacitor 122a is disposed between a first coil coupled inductor 123a and a second coil coupled inductor 123b, and the variable capacitor 122b is disposed between the first capacitor 122a and ground. However, the arrangement of the first capacitor 122a and the variable capacitor 122b is not limited to the drawings and may be changed with each other. The current divider 122 may divide the first high frequency current 111a generated by the high frequency power source 110 into a second high frequency current 111b and a third high frequency current 111c.

A ratio of a first current to a second current, such as a ratio of the second high frequency current 111b to the third high frequency current 111c may be referred to as a current ratio (CR).

The second high frequency current 111b may pass through a center antenna 125a to be described below, and the third high frequency current 111c may pass through an edge antenna 125b to be described below. In general, in typical systems, currents respectively flowing through a center antenna and an edge antenna may be generated by different high frequency power sources, and the impedances affecting (or experienced by) the currents may be respectively adjusted by matchers. According to some embodiments of the inventive concept, the first high frequency current 111a from one high frequency power source 110 may be divided into the second high frequency current 111b and the third high frequency current 111c through the current divider 122. In addition, the impedances affecting (or experienced by) the second high frequency current 111b and the third high frequency current 111c may be adjusted through the single matcher 121.

The CR may be calculated by Equation 1 below.

$$CR = \frac{\vert {i}_{Center} \vert}{\vert {i}_{Edge} \vert} = \frac{\vert {i}_{111 b} \vert}{\vert {i}_{111 c} \vert} \qquad [ Equation 1 ]$$

wherein, i_{Center} represents an amount of current passing through the center antenna 125a to be described below, i_{Edge} represents an amount of current passing through the edge antenna 125b to be described below, in represents an amount of the second high frequency current 111b, and ille represents an amount of the third high frequency current 111c.

Therefore, as described above, because the second high frequency current 111b passes through the center antenna 125a to be described below and the third high frequency current 111c passes through the edge antenna 125b to be described below, the ratio of i_{111b} to i_{111c} may be equal to the ratio of i_{Center} to i_{Edge}. In addition, in the case of an ideal circuit having no resistance on a path through which a current flows, the absolute value of i_{111b} may be equal to the absolute value of i_{Center} and the absolute value of ille may be equal to the absolute value of i_{Edge}. However, because the direction of the current is different according to the direction in which the inductor or the antenna is wound, the signs of i_{111b} and i_{Center} may be different from each other. Because the direction of the current is different according to the direction in which the inductor or the antenna is wound, the signs of i_{111c} and i_{Edge} may be different from each other. The CR may be configured to be adjusted by the capacitance of the variable capacitor 122b.

The matcher 121 may be connected to the high frequency power source 110. More specifically, the matcher 121 may be disposed between the high frequency power source 110 and the current divider 122 and connected to the high frequency power source 110 (e.g., so that an output of the high frequency power source 110 is connected to an input of the matcher 121). The matcher 121 may match the impedance affecting (or experienced by) the second high frequency current 111b with the impedance affecting (or experienced by) the third high frequency current 111c, and may be alternately described as an impedance matching circuit.

The coil coupled inductor 123 may include the first coil coupled inductor 123a configured to allow the second high frequency current 111b to flow therethrough, and the second coil coupled inductor 123b configured to allow the third high frequency current 111c to flow therethrough and connected to be adjacent to the first coil coupled inductor 123a.

The plasma generation circuit 10a may include an antenna portion 125, also described as an antenna circuit or simply an antenna assembly including at least two antennas. Although FIG. 1 illustrates that the antenna circuit 125 includes the center antenna 125a and the edge antenna 125b, the number of antennas is not limited to the drawings and may be two or more. In FIG. 1, the center antenna 125a and the edge antenna 125b are illustrated in the form of a coil, and in FIG. 2, a center antenna 225a and an edge antenna 225b included in a plasma generation circuit 10b are illustrated in a circularly turned shape with a constant radius. The center antenna 125a and the edge antenna 125b in FIG. 1 may respectively correspond to the center antenna 225a and the edge antenna 225b in FIG. 2. The center antenna 125a and the edge antenna 125b in FIG. 1 may be connected to be adjacent to each other. The center antenna 225a and the edge antenna 225b in FIG. 2 may be connected to be adjacent to each other. In the embodiment of FIG. 1, the center antenna 125a and edge antenna 125b may be more generally described as a first antenna and a second antenna. Similarly, in the embodiment of FIG. 2, the center antenna 225a and edge antenna 225b may be more generally described as a first antenna and a second antenna. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The center antenna 125a may be connected in series to the first coil coupled inductor 123a. The edge antenna 125b may be connected in series to the second coil coupled inductor 123b. The first coil coupled inductor 123a and the center antenna 125a may be configured to allow the second high frequency current 111b to flow therethrough. The second coil coupled inductor 123b and the edge antenna 225b may be configured to allow the third high frequency current 111c to flow therethrough.

According to one example, the center antenna 125a and the edge antenna 125b may be coupled adjacent to each other within a particular distance. They may have the same physical orientation (e.g., both positioned upright), and be spaced apart from each other by a particular distance. The center antenna 225a and the edge antenna 225b in FIG. 2 may also be coupled adjacent to each other within a particular distance. The center antenna 125a and the edge antenna 125b may be provided to generate first electromagnetic inductive coupling by mutual induction. Therefore, the center antenna 125a and the edge antenna 125b may be provided to have a first mutual inductance.

According to one example, the first coil coupled inductor 123a and the second coil coupled inductor 123b may be coupled within a distance adjacent to each other. The first coil coupled inductor 123a and the second coil coupled inductor 123b may be provided to generate second electromagnetic inductive coupling by mutual induction. Therefore, the first coil coupled inductor 123a and the second coil coupled inductor 123b may be provided to have a second mutual inductance.

In general, the first electromagnetic inductive coupling generates an electromagnetic field, and the electromagnetic field may cause interference in the second high frequency current 111b, the third high frequency current 111c, and the matcher 121, which are separated from each other by the current divider 122. When the second high frequency current 111b and the third high frequency current 111c are interfered with by the electromagnetic field, the control of the plasma generation rate by the center antenna 125a and the edge antenna 125b is not smooth. The second electromagnetic inductive coupling generated by the first coil coupled inductor 123a and the second coil coupled inductor 123b according to aspects of the inventive concept may cancel the first electromagnetic inductive coupling generated by the mutual induction of the center antenna 125a and the edge antenna 125b. In an embodiment, the second electromagnetic inductive coupling may have the same absolute value as the first electromagnetic inductive coupling, and the second electromagnetic inductive coupling may have a sign that is different from a sign of the first electromagnetic inductive coupling. For example, the second electromagnetic inductive coupling and the first electromagnetic inductive coupling may be formed in different directions. When the first electromagnetic inductive coupling has a positive value, the second electromagnetic inductive coupling may have a negative value. Conversely, when the first electromagnetic inductive coupling has a negative value, the second electromagnetic inductive coupling may have a positive value. When the first electromagnetic inductive coupling is canceled by the second electromagnetic inductive coupling, the interference generated in the second high frequency current 111b and the third high frequency current 111c described above be removed. Therefore, when the interference is removed, the matcher 121 may stably match the impedance affecting (or experienced by) the second high frequency current 111b with the impedance affecting (or experienced by) of the third high frequency current 111c.

In the case of FIG. 1, the center antenna 125a and the edge antenna 125b each having the coil shape may be turned in the same direction. The first coil coupled inductor 123a and the second coil coupled inductor 123b may be coiled in the same direction. The turned direction or coiled direction refers to a coiled or spiraled direction when moving along the inductor coil from a location where the coil coupled inductor (e.g., 123a or 123b) connects to the current divider (e.g., 122) toward a location where the coil coupled inductor (e.g., 123a or 123b) connects to the antenna circuit 125. Two inductors coiled in the same direction, for example, are both coiled in a clockwise, or counterclockwise manner. When two inductors are coiled in opposite directions, for example, one is coiled in a counterclockwise manner, and the other is coiled in a clockwise manner. According to an embodiment, the first coil coupled inductor 123a and the second coil coupled inductor 123b may have the same number of turns. According to an embodiment, the number of turns of the first coil coupled inductor 123a and the second coil coupled inductor 123b may be equal to the number of turns of the center antenna 125a and the edge antenna 125b each having the coil shape. For example, the number of turns of the center antenna 125a, the edge antenna 125b, the first coil coupled inductor 123a, and the second coil coupled inductor 123b may each be 3. According to an embodiment, the number of turns of the first coil coupled inductor 123a and the second coil coupled inductor 123b may be different from the number of turns of the center antenna 225a and the edge antenna 225b each having a circularly turned shape with a constant radius. For example, the number of turns of the first coil coupled inductor 123a and the second coil coupled inductor 123b may each be 3, and the number of turns of the center antenna 225a and the edge antenna 225b may each be 1. However, these are just example embodiments, and other numbers of turns may be used in either of the embodiments of FIG. 1 and FIG. 2.

The direction in which the center antenna 125a and the edge antenna 125b are coupled to each other may be different from the direction in which the first coil coupled inductor 123a and the second coil coupled inductor 123b are coupled to each other. For example, in one embodiment, both the center antenna 125a and the edge antenna 125b are coiled in the same direction, and the first coil coupled inductor 123a and the second coil coupled inductor 123b are coiled in opposite directions. Alternatively, both the center antenna 125a and the edge antenna 125b may be coiled in the same first direction, and the first coil coupled inductor 123a and the second coil coupled inductor 123b may be coiled in the same second direction, which is different from the first direction (e.g., the first direction may be clockwise, and the second direction may be counterclockwise). In one embodiment, the first coil coupled inductor 123a and the second coil coupled inductor 123b may be decoupled from each other, compared to the coupling of the center antenna 125a and the edge antenna 125b. In the decoupled case, the sign of the first electromagnetic inductive coupling generated by the mutual induction of the center antenna 125a and the edge antenna 125b may be different from the sign of the second electromagnetic inductive coupling generated by the mutual induction of the first coil coupled inductor 123a and the second coil coupled inductor 123b.

Referring to FIG. 2, the radii of circles formed when the center antenna 225a and the edge antenna 225b are turned once may be different from each other. The center antenna 225a and the edge antenna 225b may be turned in the same direction. According to an embodiment, the number of turns of the center antenna 225a may be equal to the number of turns of the edge antenna 225b. For example, the number of turns of the center antenna 225a and the number of turns of the edge antenna 225b may each be 1.

Each of the plasma generation circuits 10a and 10b may include a second capacitor 127a and a third capacitor 127b. Each of the second capacitor 127a and the third capacitor 127b may be connected to the ground. The second capacitor 127a may be connected in series with the center antenna 125a, and the third capacitor 127b may be connected in series with the edge antenna 125b. In addition, the third capacitor 127b and the second capacitor 127a may each be connected to a common node on one end (e.g. ground) and a similar component on the other end (e.g., an antenna 225). Each of the second capacitor 127a and the third capacitor 127b may cancel noise generated from the center antenna 125a and the edge antenna 125b.

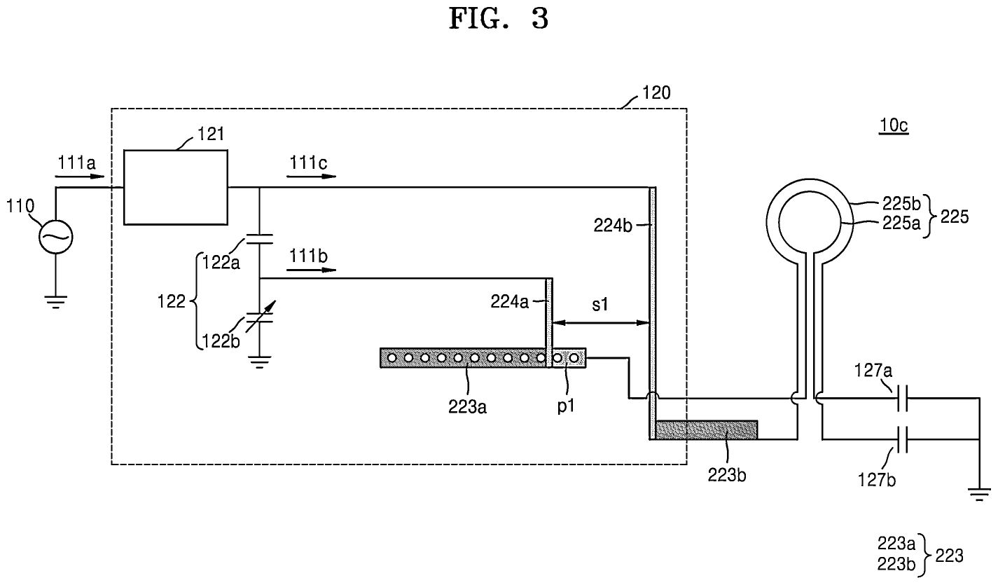

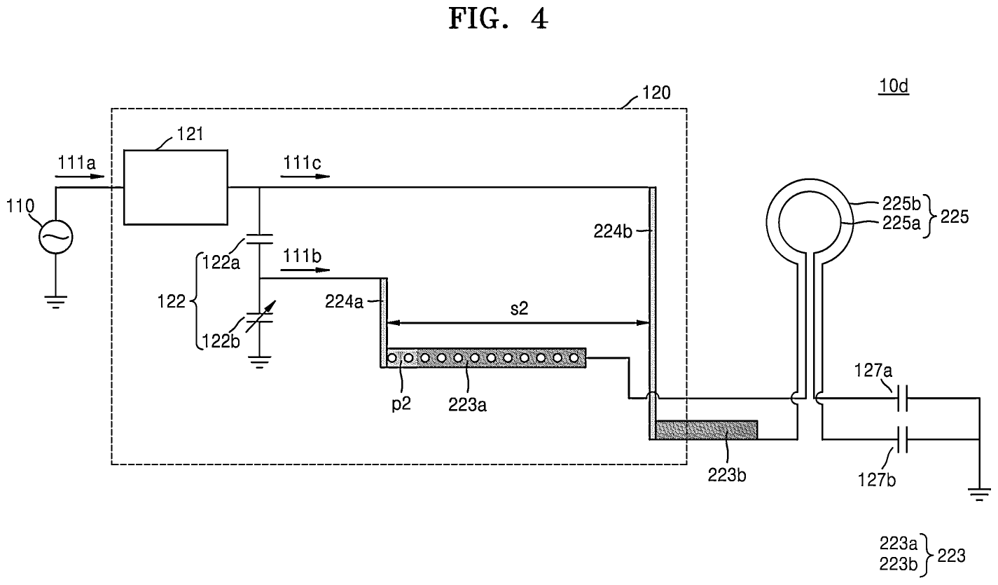

FIG. 3 is a circuit diagram of a plasma generation circuit including a busbar inductor, according to an embodiment. FIG. 4 is a circuit diagram of a plasma generation circuit including a busbar inductor, according to another embodiment. Hereinafter, differences from FIGS. 1 and 2 are mainly described.

Referring to FIGS. 3 and 4, plasma generation circuits 10c and 10d may each include a plurality of busbar connection portions 223, and a first busbar coupled inductor 224a and a second busbar coupled inductor 224b connected to the busbar connection portions 223. More specifically, the busbar connection portions 223 may include a first busbar connection portion 223a and a second busbar connection portion 223b. Each busbar connection portion may be described as a connecting bar, and may be in the form of a flat, metal, rectangular bar in some embodiments.

In the busbar coupled inductor and busbar connection portions mentioned in the present invention, the busbar can be formed of a wide and flat metal plate or a structure in which several layers of thin metal plates are stacked. The busbar coupled inductor and the busbar connection portions can act as a single inductor as a whole. According to one example, the busbar coupled inductor can provide a positional reference for being coupled to the busbar connection portions. The busbar connection portions of the present invention can be physically coupled to the busbar coupled inductor according to the positional reference provided by the busbar connection portions. The busbar connection portions are physically coupled to the busbar coupled inductor, and the size of the interaction can be adjusted by the distance difference from other busbar connection portions. Here, the interaction between busbar connection portions can correspond to the interaction between coil inductors. According to one example, multiple coils can be arranged in the busbar connection portions and the busbar coupled inductor. When current flows through the busbar connection portions and the busbar coupled inductor, a magnetic field can be generated by the interaction of the currents in the multiple arranged coils.

The first busbar connection portion 223a may be connected in series with the first busbar coupled inductor 224a, and the second busbar connection portion 223b may be connected in series with the second busbar coupled inductor 224b. In addition, the first busbar connection portion 223a may be connected in series with the center antenna 225a and may be connected to the high frequency power source 110, and the second busbar connection portion 223b may be connected in series with the edge antenna 225b and may be connected to the high frequency power source 110. The first busbar connection portion 223a and the second busbar connection portion 223b may each be connected between one end of a respective busbar coupled inductor (224a or 224b) and one end of a respective antenna (225a or 225b). The first busbar coupled inductor 224a and the second busbar coupled inductor 224b may each be connected between one end of a respective busbar connection portion (223a or 223b) and one respective end of capacitor 122a.

The first busbar connection portion 223a, the first busbar coupled inductor 224a, and the center antenna 125a may be configured to allow the second high frequency current 111b to flow therethrough. The second busbar connection portion 223b, the second busbar coupled inductor 224b, and the edge antenna 225b may be configured to allow the third high frequency current 111c to flow therethrough.

According to one example, the first busbar coupled inductor 224a and the second busbar coupled inductor 224b may be coupled within a distance adjacent to each other. The first busbar coupled inductor 224a and the second busbar coupled inductor 224b may be positioned to be parallel to each other. The first busbar coupled inductor 224a and the second busbar coupled inductor 224b may be provided to generate second electromagnetic inductive coupling by mutual induction. For example, the first busbar coupled inductor 224a and the second busbar coupled inductor 224b may be provided to have a second mutual inductance.

In the first busbar connection portion 223a, a portion closer to the second busbar connection portion 223b may be as a first point p1, and a portion farther from the second busbar connection portion 223b may be a second point p2. The first busbar coupled inductor 224a may be configured to be movable along an axis parallel to the direction in which the first busbar connection portion 223a extends within the length range between the first point p1 and the second point p2 so as to control the magnitude of the second electromagnetic inductive coupling. When the first busbar coupled inductor 224a is located at the first point p1, the horizontal distance between the first busbar coupled inductor 224a and the second busbar coupled inductor 224b is a first distance s1. Referring to FIG. 4, when the first busbar coupled inductor 224a is located at the second point p2, the horizontal distance between the first busbar coupled inductor 224a and the second busbar coupled inductor 224b is a second distance s2. The magnitude of the second electromagnetic inductive coupling generated when the first busbar coupled inductor 224a is located at the first point p1 may be greater than the magnitude of the second electromagnetic inductive coupling generated when the first busbar coupled inductor 224a is located at the second point p2. For example, the coupling of the first busbar coupled inductor 224a and the second busbar coupled inductor 224b when the first busbar coupled inductor 224a is located at the first point p1 may be stronger than the coupling of the first busbar coupled inductor 224a and the second busbar coupled inductor 224b when the first busbar coupled inductor 224a is located at the second point p2. The magnitude of the second electromagnetic inductive coupling may be inversely proportional to the distance in the horizontal direction.

According to aspects of the inventive concept, the second electromagnetic inductive coupling generated by the first busbar coupled inductor 224a and the second busbar coupled inductor 224b may cancel the first electromagnetic inductive coupling generated by mutual induction of the center antenna 225a and the edge antenna 225b.

The direction in which the center antenna 125a and the edge antenna 125b are coupled to each other may be different from the direction in which the first busbar coupled inductor 224a and the second busbar coupled inductor 224b are coupled to each other. For example, the first busbar coupled inductor 224a and the second busbar coupled inductor 224b may be decoupled from each other, compared to the coupling of the center antenna 125a and the edge antenna 125b. In the decoupled case, the sign of the first electromagnetic inductive coupling generated by the mutual induction of the center antenna 125a and the edge antenna 125b may be different from the sign of the second electromagnetic inductive coupling generated by the mutual induction of the first busbar coupled inductor 224a and the second busbar coupled inductor 224b.

As stated, the multiple coils arranged in the busbar coupled inductor and the busbar connection portions can rotate in different or the same directions. The coupling and decoupling can be determined based on the orientation of the multiple coils arranged in different directions.

In some embodiments, the second electromagnetic inductive coupling and the first electromagnetic inductive coupling may result in electromagnetic fields formed in different directions. When the first electromagnetic inductive coupling has a positive value, the second electromagnetic inductive coupling may have a negative value. Conversely, when the first electromagnetic inductive coupling has a negative value, the second electromagnetic inductive coupling may have a positive value. When the first electromagnetic inductive coupling is canceled by the second electromagnetic inductive coupling, the interference generated in the second high frequency current 111b and the third high frequency current 111c described above may be removed. Therefore, when the interference is removed, the matcher 121 may stably match the impedance affecting (or experienced by) the second high frequency current 111b with the impedance affecting (or experienced by) the third high frequency current 111c.

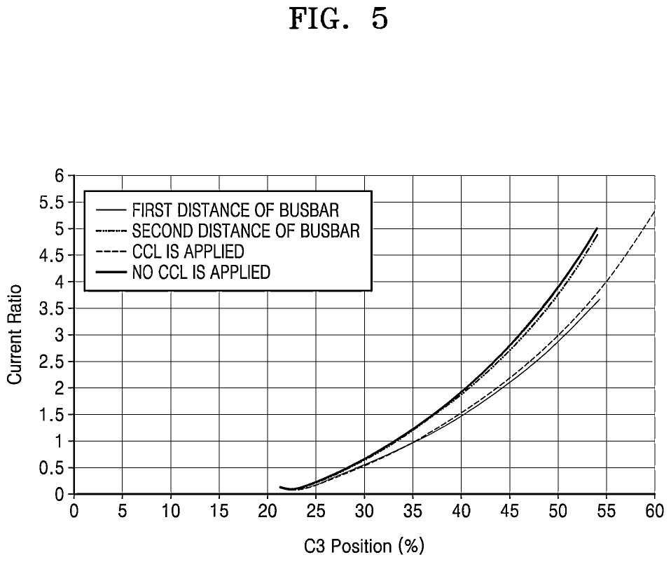

FIG. 5 is a graph of the CR according to the position of the variable capacitor, according to an embodiment.

Referring to FIG. 5 together with FIGS. 1 to 4, C3 on the X-axis may correspond to the variable capacitor 122b. CCL is a counter coupled inductor and may correspond to the first and second coil coupled inductors 123a and 123b each having a coil shape. The busbar may correspond to the first and second busbar coupled inductors 224a and 224b. The Y-axis represents the CR.

As the position of the variable capacitor 122b increases, the CR may increase. In general, control may be facilitated only when the CR increases linearly in proportion to the position of the variable capacitor 122b. As described above, the second high frequency current 111b, the third high frequency current 111c, and the matcher 121 are interfered by the inductance generated by mutual coupling of a plurality of antennas included in the antenna portion. Due to the interference, the CR does not increase linearly in proportion to the position of the variable capacitor 122b. More specifically, as the CR decreases, the change in position of the variable capacitor 122b may increase.

When the distance between the busbar coupled inductors is the second distance or when the CCL is not applied, the coupled strength is weak and thus, the graph does not increase linearly. On the other hand, when the distance between the busbar coupled inductors is the first distance or when the CCL is applied, the coupled strength is strong, and thus, it may be confirmed that the graph increases more linearly, compared to the case where the distance between the busbar coupled inductors is the second distance or when the CCL is not applied. In these examples, the first distance is smaller than the second distance. This is because, as described above, the first electromagnetic inductive coupling by the antenna portion is canceled by the second electromagnetic inductive coupling by the mutual coupling of the coil coupled inductors or the busbar coupled inductors.

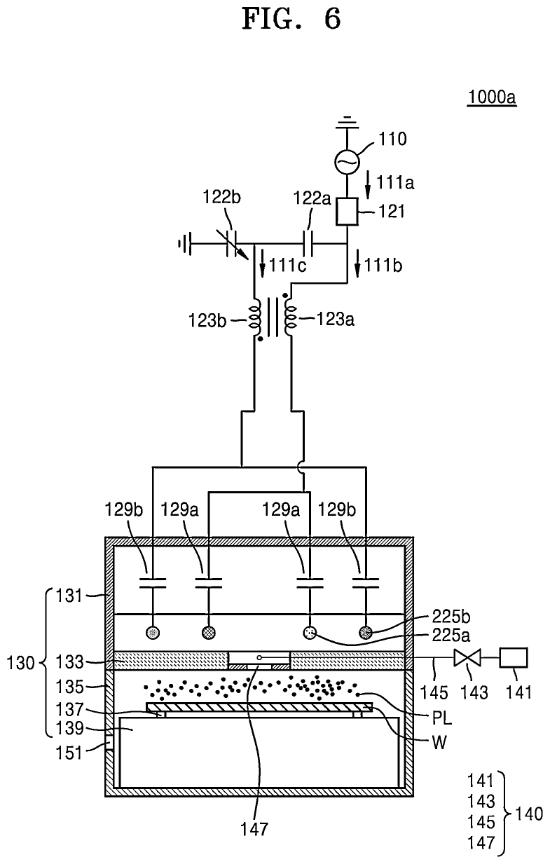

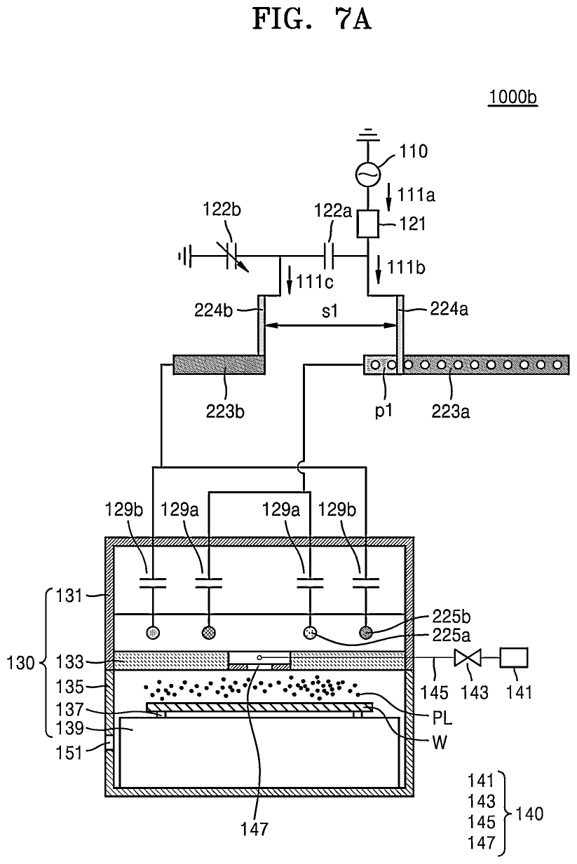

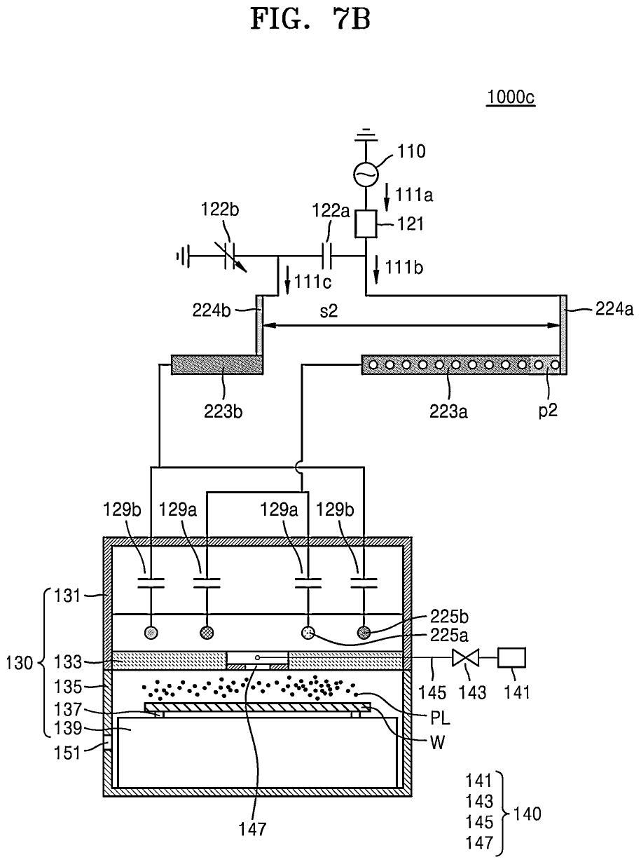

FIG. 6 is a diagram for describing a substrate processing device including a coil inductor, according to an embodiment. FIG. 7A is a diagram for describing a substrate processing device including a busbar inductor, according to an embodiment. FIG. 7B is a diagram for describing a substrate processing device including a busbar inductor, according to another embodiment. Hereinafter differences from FIGS. 1 to 4 are mainly described.

Referring to FIGS. 6 to 7B together with FIGS. 1 to 4, substrate processing devices 1000a and 1000b may each include a chamber 130 defining a space for plasma-processing a substrate W, a gas supply portion 140 that supplies plasma gas to the chamber 130, and plasma generation circuits that induce a plasma generation reaction of the plasma gas. For example, the substrate processing devices 1000a and 1000b may include the plasma generation circuits 10a, 10b, 10c, or 10d illustrated in FIGS. 1 to 4.

The substrate processing devices 1000a and 1000b may process the substrate W in the process chamber by using plasma. For example, the substrate processing devices 1000a and 1000b may each be a plasma etching device capable of performing a plasma etching process. The substrate processing devices 1000a and 1000b may be configured to perform a semiconductor device manufacturing process. The substrate processing devices 1000a and 1000b may each include a capacitively coupled plasma source, an inductively coupled plasma source, a microwave plasma source, and a remote plasma source. The substrate processing devices 1000a and 1000b according to aspects of the inventive concept may perform a plasma process by using the inductively coupled plasma source. The substrate processing devices 1000a and 1000b may perform substrate processing processes, such as plasma annealing, etching, plasma enhanced chemical vapor deposition, plasma enhanced atomic layer deposition, physical vapor deposition, and plasma cleaning.

The substrate processing devices 1000a and 1000b may perform, for example, a reactive ion etching process. The reactive ion etching is a dry etching process in which excited species (radicals, ions, etc.) excited by a high frequency RF power source etch a substrate or a thin-film in a low-pressure chamber. The reactive ion etching may be performed by bombardment of energetic ions and a complexity of physical and chemical actions of chemically active species. The reactive ion etching may include etching of insulating layers such as silicon oxide, etching of metallic materials, and etching of doped or undoped semiconductor materials. The substrate processing devices 1000a and 1000b may be devices for processing the substrate W by using the generated plasma.

The substrate W may be a wafer, for example a silicon wafer. The substrate W may include a semiconductor element such as germanium (Ge), or a compound semiconductor such as silicon carbide (SiC), gallium arsenide (GaAs), indium arsenide (InAs), and indium phosphide (InP). The substrate W may have a silicon-on-insulator (SOI) structure. The substrate W may include a buried oxide layer. The substrate W may include conductive regions, for example, wells doped with impurities. The substrate W may have various device isolation structures such as shallow trench isolation (STI) that separates the doped wells from each other. The substrate W may have a first surface that is an active surface and a second surface that is an inactive surface opposite to the first surface. The second surface of the substrate W may face a chuck 137 to be described below. A material layer, for example, an oxide layer or a nitride layer, may be formed on the substrate W.

The chamber 130 may include an upper housing 131, a lower housing 135 disposed below the upper housing 131, a window 133 disposed between the upper housing 131 and the lower housing 135, and the chuck 137 that supports the substrate W. A chuck support 139 may be disposed below the chuck 137.

The chamber 130 may be, for example, a plasma chamber 130. The chamber 130 may include a metal such as aluminum. The chamber 130 may have a substantially cylindrical shape. The chamber 130 may provide a process space for processing the substrate W. The process space may be defined by the upper housing 131 and the lower housing 135. The chamber 130 may isolate the process space from the outside. Accordingly, parameters, such as pressure, temperature, partial pressure of process gas, and plasma density may be precisely controlled. The chamber 130 (internal space) may have cylindrical symmetry.

According to embodiments, the chamber 130 may provide a plasma region. The plasma region refers to a space affected by plasma, such as a sheath region and a space where plasma is formed during processing of the substrate W. The plasma region may simply indicate a space between the chuck 137 and the window 133.

A center antenna 225a and an edge antenna 225b spaced upward from the chuck 137 may be provided in the upper housing 131. The center antenna 225a and the edge antenna 225b may be fixed to the upper portion of the window 133. The center antenna 225a and the edge antenna 225b may face the chuck 137. The center antenna 225a and the edge antenna 225b may be connected to a high frequency power source 110. The high frequency power source 110 may generate RF power and supply the generated RF power to the center antenna 225a and the edge antenna 225b through an impedance matcher.

The gas supply portion 140 may include a gas source 141 that supplies gas to the chamber 130, a gas valve 143 that is connected to the gas source 141 and controls the amount of gas supplied to the chamber 130, a gas supply line 145 that provides a path through which the gas moves, and a gas supply nozzle 147 that supplies gas between the window 133 and the substrate W.

The gas supply nozzle 147 may uniformly disperse the process gas introduced into the chamber 130. The gas supply nozzle 147 may be disposed in the internal space of the chamber 130. The gas supply nozzle 147 may face the chuck 137. The gas supply nozzle 147 may have an annular sidewall and a disk-shaped spray plate. A plurality of spray holes may be formed in the entire region of the spray plate. The process gas supplied through the gas source 141 may be sprayed into the internal space of the chamber 130 through the spray holes of the gas supply nozzle 147. The chamber 130 may further include an exhaust device that exhausts reactants, debris, process gas, and plasma after processing the substrate W. In an embodiment, the exhaust device may be an exhaust hole 151.

The chuck 137 may be provided on the chuck support 139 and may support the substrate W disposed thereon. The chuck 137 may be an electrostatic chuck (ESC) configured to fix the substrate W by electrostatic force. The chuck 137 may fix the substrate W by using electrostatic force. The chuck 137 may be provided in a process chamber configured to perform a semiconductor manufacturing process using plasma, for example, etching, deposition, cleaning, etc.

The substrate processing devices 1000a and 1000b may each include a first filter capacitor 129a disposed between the center antenna 225a and the coupled inductor and connected in series to the center antenna 225a, and a second filter capacitor 129b disposed between the edge antenna 225b and the coupled inductor and connected in series to the edge antenna 225b. The coupled inductor may be the first coil coupled inductor 123a and the second coil coupled inductor 123b illustrated in FIG. 6, or may be the first busbar coupled inductor 224a and the second busbar coupled inductor 224b illustrated in FIG. 7A.

The center antenna 225a and the edge antenna 225b may be disposed between the upper housing 131 and the window 133. The center antenna 225a may be disposed above the center of the window 133 and may be configured to induce generation of plasma at the center of the substrate W. The edge antenna 225b may be disposed above the edge of the window 133 and may be configured to induce generation of plasma at the edge of the substrate W. The center antenna 225a and the edge antenna 225b may be turned in the same direction.

The amount of the second high frequency current 111b transferred to the center antenna 225a may be proportional to the amount of the plasma generated by the center antenna 225a, and the amount of the plasma generated by the center antenna 225a may be proportional to the etch rate for the center of the substrate W. In addition, the amount of the third high frequency current 111c transferred to the edge antenna 225b may be proportional to the amount of the plasma generated by the edge antenna 225b, and the amount of the plasma generated by the edge antenna 225b may be proportional to the etch rate for the edge of the substrate W. Therefore, the substrate processing devices 1000a and 1000b may be configured to control the CR by adjusting the capacitance of the variable capacitor 122b and control the etch rate at the center of the substrate W and the edge of the substrate W through the controlled CR.

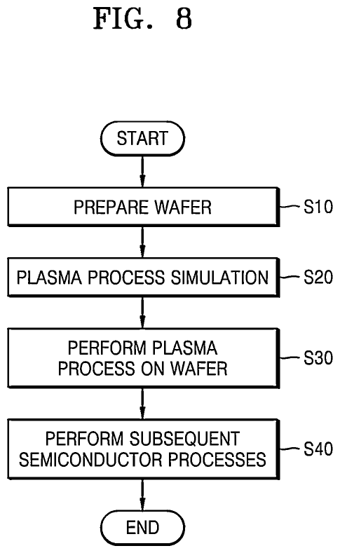

FIG. 8 is a flowchart of a semiconductor device manufacturing method including plasma process simulation, according to an embodiment.

Referring to FIG. 8, the substrate W may be prepared in the chamber 130 (S10). For example, the substrate W may be disposed on the chuck 137 of the chamber 130. The chuck 137 may be a stage that supports the substrate W. For example, the chuck 137 may be an ESC.

Thereafter, a plasma process simulation may be performed on the substrate W (S20). For example, the plasma process may include any plasma processes, such as a plasma etching process, a plasma annealing process, and/or a plasma cleaning process.

The plasma process simulation in operation S20 may include defining a plasma reaction, calculating reaction parameters, generating a plasma process simulation profile, and generating a final simulation profile.

Thereafter, a plasma process may be performed on the substrate W based on the plasma process simulation (S30). The plasma process may include etching, deposition, and cleaning processes that are performed on the substrate W by using plasma. During the plasma process, compensative inductive coupling may be implemented, as discussed in the embodiments above, to counteract inductive coupling by the antenna used for the plasma process.

After the plasma process is performed on the substrate W, subsequent semiconductor processes may be performed on the substrate W (S40). The subsequent semiconductor processes performed on the substrate W may include various processes. For example, the subsequent semiconductor processes may include a deposition process, an etching process, an ion process, a cleaning process, etc. The subsequent semiconductor processes may or may not use plasma. In addition, the subsequent semiconductor processes may include a singulation process for individualizing the substrate W into semiconductor chips, a test process for testing the semiconductor chips, and a packaging process for packaging the semiconductor chips. A semiconductor device may be completed through the subsequent semiconductor processes on the substrate W.

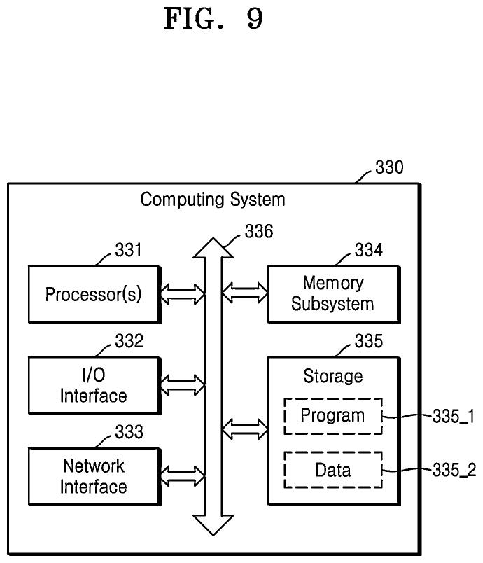

FIG. 9 is a block diagram illustrating a computing system according to an embodiment. In some embodiments, the plasma process simulation in operation S20 may be performed in a computing system 330 of FIG. 9.

Referring to FIG. 9, the computing system 330 may be a stationary computing system, such as a desktop computer, a workstation, or a server, or may be a portable computing system, such as a laptop computer. As illustrated in FIG. 9, the computing system 330 may include at least one processor 331, an input/output (I/O) interface 332, a network interface 333, a memory subsystem 334, and a storage 335. The at least one processor 331, the I/O interface 332, the network interface 333, the memory subsystem 334, and the storage 335 may communicate with each other through a bus 336.

The at least one processor 331 may also be referred to as a processing unit. Examples of the at least one processor 331 may include a microprocessor, an application processor (AP), a digital signal processor (DSP), or a graphic processing unit (GPU), which executes any instruction sets (e.g., Intel Architecture-32 (IA-32), 64-bit extended IA-32, x86-64, PowerPC, Sparc, MIPS, ARM, IA-64, etc.). For example, the at least one processor 331 may access the memory subsystem 334 through the bus 336 and execute instructions stored in the memory subsystem 334.

The I/O interface 332 may include an input device, such as a keyboard or a pointing device, and/or an output device, such as a display device or a printer, or may provide access to the input device and/or the output device. A user may use the I/O interface 332 to trigger execution of a program 335_1 and/or loading of data 335_2, to input ion information, material information, and/or neutral radical information, and to confirm output data.

The network interface 333 may provide access to a network outside the computing system 330. For example, the network may include a plurality of computing systems and communication links. The communication links may include wired links, optical links, wireless links, or any other type of links.

The memory subsystem 334 may store all or at least part of the program 335_1 for a method of modeling damage due to incident particles described above with reference to the drawings. The at least one processor 331 may perform at least some operations included in the method of modeling damage due to incident particles by executing the program (or instructions) stored in the memory subsystem 334. The memory subsystem 334 may include read-only memory (ROM), random access memory (RAM), etc.

The storage 335 may be a non-transitory storage medium and may not lose stored data even when power supplied to the computing system 330 is interrupted. For example, the storage 335 may include a non-volatile memory device, or may include a storage medium, such as magnetic tape, optical disk, or magnetic disk. In addition, the storage 335 may be removable from the computing system 330. As illustrated in FIG. 9, the storage 335 may store the program 335_1 and data 335_2. Before the program 335_1 is executed by the at least one processor 331, at least a portion of the program 335_1 may be loaded into the memory subsystem 334. In some embodiments, the storage 335 may store a file written in a program language, and all or at least part of the program 335_1 generated from the file by a compiler or the like may be loaded into the memory subsystem 334. The data 335_2 may include data (e.g., ion information, material information, and/or neutral radical information) used to perform the plasma process simulation described above with reference to the drawings. In addition, the data 335_2 may include output data generated by performing the plasma process simulation described above with reference to the drawings.

While the inventive concept has been particularly shown and described with reference to embodiments thereof, it will be understood that various changes in form and details may be made therein without departing from the spirit and scope of the following claims.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact

What is claimed is:

1. A plasma generation circuit comprising:
a high frequency power source configured to generate a first high frequency current;
a current divider comprising a first capacitor and a variable capacitor and configured to divide the first high frequency current into a second high frequency current and a third high frequency current;
an antenna assembly comprising a center antenna connected to the current divider and through which the second high frequency current is configured to flow, and an edge antenna connected in to the current divider and through which the third high frequency current is configured to flow, the antenna assembly being configured to induce generation of an inductively coupled plasma;
a first coil coupled inductor configured to allow the second high frequency current to flow therethrough; and
a second coil coupled inductor configured to allow the third high frequency current to flow therethrough and adjacent to the first coil coupled inductor.

2. The plasma generation circuit of claim 1, wherein:
the center antenna and the edge antenna are provided to generate a first electromagnetic inductive coupling by mutual induction,
the first coil coupled inductor and the second coil coupled inductor are provided to generate a second electromagnetic inductive coupling in a direction opposite to a direction of the first electromagnetic inductive coupling, and
the first electromagnetic inductive coupling is canceled by the second electromagnetic inductive coupling.

3. The plasma generation circuit of claim 1, wherein the first coil coupled inductor and the second coil coupled inductor are disposed between the current divider and the antenna assembly.

4. The plasma generation circuit of claim 1, wherein:
the first capacitor is disposed between the center antenna and the edge antenna, and
a current ratio of the second high frequency current to the third high frequency current is adjusted by a capacitance of the variable capacitor.

5. The plasma generation circuit of claim 1, further comprising:
a second capacitor disposed between the center antenna and ground and connected in series with the center antenna; and
a third capacitor disposed between the edge antenna and ground and connected in series with the edge antenna.

6. The plasma generation circuit of claim 1, wherein the center antenna and the edge antenna include coils that are turned in the same direction.

7. A plasma generation circuit comprising:
a high frequency power source configured to generate a first high frequency current;
a current divider comprising a first capacitor and a variable capacitor and configured to divide the first high frequency current into a second high frequency current and a third high frequency current;
an antenna assembly comprising a center antenna connected to the current divider and through which the second high frequency current is configured to flow, and an edge antenna connected to the current divider and through which the third high frequency current is configured to flow, the antenna assembly being configured to induce generation of an inductively coupled plasma;
a first busbar coupled inductor configured to allow the second high frequency current to flow therethrough;
a second busbar coupled inductor configured to allow the third high frequency current to flow therethrough, and disposed to be apart from the first busbar coupled inductor in a horizontal direction;
a first busbar connection portion connected in series with the first busbar coupled inductor; and
a second busbar connection portion connected in series with the second busbar coupled inductor.

8. The plasma generation circuit of claim 7, wherein:
the center antenna and the edge antenna are provided to generate a first electromagnetic inductive coupling by mutual induction,
the first busbar coupled inductor and the second busbar coupled inductor are provided to generate a second electromagnetic inductive coupling in a direction opposite to a direction of the first electromagnetic inductive coupling, and
the first electromagnetic inductive coupling is canceled by the second electromagnetic inductive coupling.

9. The plasma generation circuit of claim 8, wherein:
a portion of the first busbar connection portion relatively closer to the second busbar connection portion is at a first point, and a portion of the first busbar connection portion relatively further from the second busbar connection portion is at a second point,
the first busbar coupled inductor is configured to be movable along an axis parallel to an extension direction of the first busbar connection portion within a length range between the first point and the second point so as to adjust a magnitude of the second electromagnetic inductive coupling,
when the first busbar coupled inductor is located at the first point, a horizontal distance between the first busbar coupled inductor and the second busbar coupled inductor is a first distance,
when the first busbar coupled inductor is located at the second point, a horizontal distance between the first busbar coupled inductor and the second busbar coupled inductor is a second distance, and
a magnitude of the second electromagnetic inductive coupling generated when the first busbar coupled inductor is located at the first point is greater than a magnitude of the second electromagnetic inductive coupling generated when the first busbar coupled inductor is located at the second point.

10. The plasma generation circuit of claim 7, wherein the first busbar coupled inductor and the second busbar coupled inductor are disposed between the current divider and the antenna assembly.

11. The plasma generation circuit of claim 7, wherein:
the first capacitor is disposed between the center antenna and the edge antenna, and
a current ratio of the second high frequency current to the third high frequency current is adjusted by a capacitance of the variable capacitor.

12. The plasma generation circuit of claim 7, further comprising:
a second capacitor disposed between the center antenna and ground and connected in series with the center antenna; and
a third capacitor disposed between the edge antenna and ground and connected in series with the edge antenna.

13. A plasma generation circuit comprising:
a gas supply portion configured to supply plasma gas to a chamber configured to define a space for plasma-processing a substrate;
a high frequency power source configured to generate a first high frequency current;
a current divider comprising a first capacitor and a variable capacitor and configured to divide the first high frequency current into a second high frequency current and a third high frequency current;
an antenna assembly comprising a center antenna connected to the current divider and through which the second high frequency current is configured to flow, and an edge antenna connected to the current divider and through which the third high frequency current is configured to flow, the antenna assembly being configured to induce generation of an inductively coupled plasma; and
a coupled inductor disposed between the current divider and the antenna assembly,
wherein:
the center antenna and the edge antenna are provided to generate a first electromagnetic inductive coupling by mutual induction,
the coupled inductor is provided to generate a second electromagnetic inductive coupling in a direction opposite to a direction of the first electromagnetic inductive coupling, and
the first electromagnetic inductive coupling is canceled by the second electromagnetic inductive coupling,
wherein the chamber comprises:
an upper housing;
a lower housing disposed below the upper housing;
a window disposed between the upper housing and the lower housing; and
a chuck configured to support the substrate.

14. The plasma generation circuit of claim 13, wherein the coupled inductor comprises:
a first coil coupled inductor configured to allow the second high frequency current to flow therethrough; and
a second coil coupled inductor configured to allow the third high frequency current to flow therethrough and adjacent to the first coil coupled inductor.

15. The plasma generation circuit of claim 13, wherein the coupled inductor comprises:
a first busbar coupled inductor configured to allow the second high frequency current to flow therethrough;
a second busbar coupled inductor configured to allow the third high frequency current to flow therethrough, and disposed to be apart from the first busbar coupled inductor in a horizontal direction;
a first busbar connection portion connected in series with the first busbar coupled inductor; and
a second busbar connection portion connected in series with the second busbar coupled inductor,
wherein,
a portion of the first busbar connection portion relatively closer to the second busbar connection portion is at a first point, and a portion of the first busbar connection portion relatively further from the second busbar connection portion is at a second point,
the first busbar coupled inductor is configured to be movable along an axis parallel to an extension direction of the first busbar connection portion within a length range between the first point and the second point so as to adjust a magnitude of the second electromagnetic inductive coupling,
when the first busbar coupled inductor is located at the first point, a horizontal distance between the first busbar coupled inductor and the second busbar coupled inductor is a first distance,
when the first busbar coupled inductor is located at the second point, a horizontal distance between the first busbar coupled inductor and the second busbar coupled inductor is a second distance, and
a magnitude of the second electromagnetic inductive coupling generated when the first busbar coupled inductor is located at the first point is greater than a magnitude of the second electromagnetic inductive coupling generated when the first busbar coupled inductor is located at the second point.

16. The plasma generation circuit of claim 13, further comprising:
a first filter capacitor disposed between the center antenna and the coupled inductor and connected in series to the center antenna; and
a second filter capacitor disposed between the edge antenna and the coupled inductor and connected in series to the edge antenna.

17. The plasma generation circuit of claim 13, wherein:
the center antenna and the edge antenna are disposed between the upper housing and the window,
the center antenna is disposed above a center of the window and is configured to induce generation of plasma at a center of the substrate,
the edge antenna is disposed above an edge of the window and is configured to induce generation of plasma at an edge of the substrate, and
the center antenna and the edge antenna include coils that are turned in the same direction.

18. The plasma generation circuit of claim 13, wherein:
the first capacitor is disposed between the center antenna and the edge antenna, and
a current ratio of the second high frequency current to the third high frequency current is adjusted by a capacitance of the variable capacitor.

19. The plasma generation circuit of claim 13, wherein the current divider is further configured to control an etch rate at a center of the substrate and an edge of the substrate by adjusting a capacitance of the variable capacitor.

20. The plasma generation circuit of claim 13, wherein the gas supply portion comprises:
a gas source configured to supply gas to the chamber;
a gas valve connected to the gas source and configured to control an amount of the gas supplied to the chamber;
a gas supply line configured to provide a path through which the gas moves; and
a gas supply nozzle configured to supply the gas between the window and the substrate.
